(19) United States
(12) Patent Application Publication
(10) Pub. No.: US 2011/0013350 A1
(43) Pub. Date: Jan. 20, 2011

(54) Friction Mechanisms For Computing Devices

(76) Inventors: Mark S. Tracy, Tomball, TX (US); Dustin L. Hoffman, Cypress, TX (US); Jeffrey A. Lev, Tomball, TX (US); Paul J. Doczy, Cypress, TX (US)

Correspondence Address: HEWLETT-PACKARD COMPANY;Intellectual Property Administration, 3404 E. Harmony Road, Mail Stop 35, FORT COLLINS, CO, 80528, US

(21) Appl. No.: 12/866,678

(22) PCT Filed: Mar. 4, 2008
(86) PCT No.: PCT/US2008/055791

§ 371 Date: Aug. 6, 2010

(51) Int. Cl. G06F 1/16; E05D 11/08; E05D 11/10; H05K 7/14

(52) U.S. Cl. 361/679.21; 16/342; 16/321; 248/205.1

(57) ABSTRACT

A friction mechanism for use in a computing device having a base portion and a display portion. In one embodiment, the friction mechanism includes a shaft adapted to be supported by the base portion of the computing device and having ends adapted to be fixedly secured to the display portion of the computing device, a brake disk mounted on the shaft, and a brake pad in contact with the brake disk that resists rotation of the brake disk such that the brake disk, the shaft on which the brake disk is mounted, and the display portion to which the shaft is fixedly secured cannot freely pivot relative to the base portion of the computing device.

### BACKGROUND

Notebook computers often comprise friction hinges that are designed to hold display portions of the computers in desired positions. Alternative means for providing such friction are desired to provide new options for notebook computer design and construction.

### BRIEF DESCRIPTION OF THE DRAWINGS

The disclosed friction mechanisms can be better understood with reference to the following drawings. The components in the drawings are not necessarily to scale.

FIG. 1 is a perspective view of an embodiment of a computing device that incorporates a friction mechanism.

FIG. 2 is a perspective view of an embodiment of the friction mechanism shown in FIG. 1.

### DETAILED DESCRIPTION

As described above, alternative means for controlling display portions are desired. Disclosed in the following are embodiments of friction mechanisms that can provided such control. In some embodiments, the friction mechanisms comprise a disk brake that provides resistance against pivoting of the display portion.

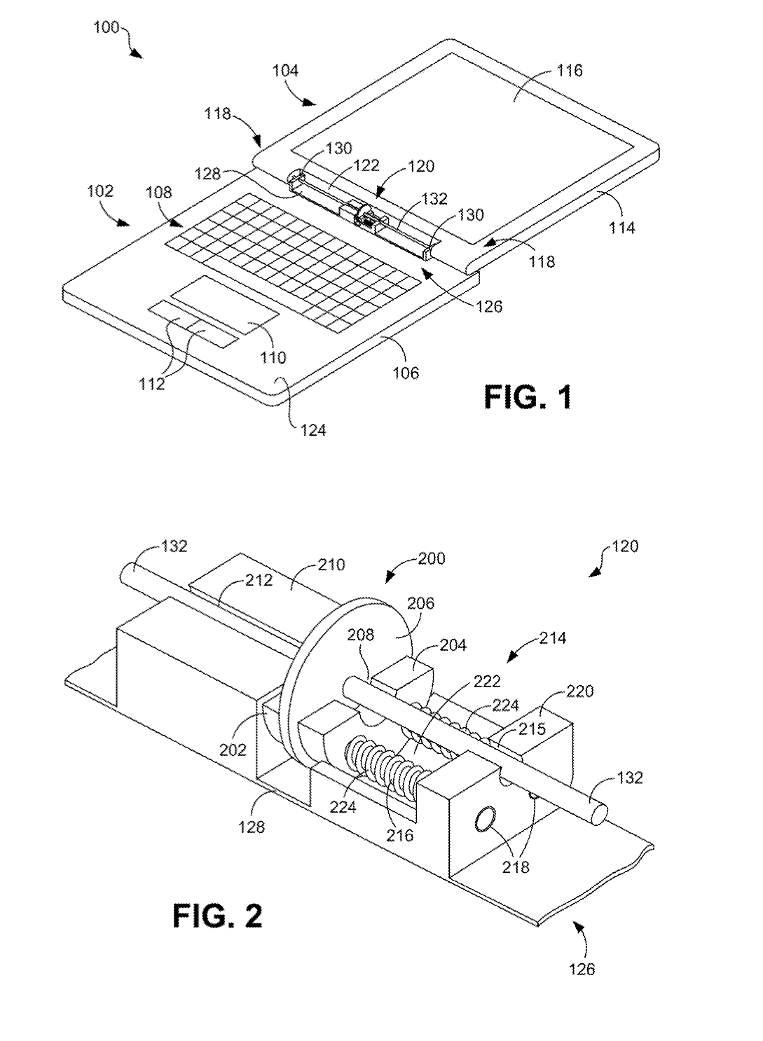

Turning to the figures, in which like numerals identify corresponding components, illustrated in FIG. 1 is an embodiment of a computing device 100 configured as a notebook or “laptop” computer. The computing device 100 generally comprises a base portion 102 and a display portion 104. The base portion 102 comprises a housing 106 that contains various internal components of the computing device 100, such as one or more processors, memory, a hard drive, and the like. Also comprised by the base portion 102 is a user interface including a keyboard 108, a touch pad 110, and selection buttons 112. The display portion 104 also comprises a housing 114. The housing 114 surrounds a display 116, such as a liquid crystal display (LCD).

The display portion 104 is pivotally attached to the base portion 102 with hinges 118. In the embodiment of FIG. 1, the hinges 118 are positioned at the lateral edges of the display portion 104 and, unlike the hinges of conventional notebook computers, comprise no internal friction elements. Accordingly, the hinges 118 are simple hinges that do not resist pivoting of the display portion 104 relative to the base portion 102.

Positioned between the hinges 118, however, is a friction mechanism or brake 120 that provides resistance to pivoting of the display portion 104 so that the portion will remain in substantially any position a user places it relative to the base portion 102. Although the friction mechanism 120 is visible in FIG. 1, it is noted that the friction mechanism normally is covered by a cover panel that has been omitted from the figure for purposes of explaining the friction mechanism. As indicated in FIG. 1, the friction mechanism 120 is positioned within a gap 122 defined by the display portion 104 between its hinges 118. Such positioning, among other things, enables the display portion 104 to be pivoted without interference from the friction mechanism 120 (other than the resistance it provides). As is further apparent in FIG. 1, the friction mechanism 120 is mounted to or integrated with a mounting bracket 126 that is mounted to the top surface 124 of the base portion 102. The bracket 126 includes a base 128 and vertical supports 130 that extend upward from each end of the base. The supports 130 support and retain an elongated shaft 132 that extends between the hinges 118 and passes through the friction mechanism 120. The shaft 132 is fixedly secured at each of its ends to a hinge 118 such that the shaft rotates about its longitudinal axis and within the supports 130 when the display portion 104 is pivoted relative to the base portion 102. Notably, although the bracket 126 has been described as being mounted to the surface 124 of the base portion 102, the bracket could be integrated with the base portion in other ways.

FIG. 2 illustrates the friction mechanism 120 in greater detail. As indicated in FIG. 2, the friction mechanism 120 includes a circular friction or brake disk 200 that is fixedly mounted to the shaft 132 such that the disk rotates in unison with the shaft. In some embodiments, both the brake disk 200 and the shaft 132 are formed of a metal, such as stainless steel. Alternatively, however, the brake disk 200 can be formed of another suitable material, such as a high performance plastic material.

As is further indicated in FIG. 2, the brake disk 200 is flanked by first and second friction or brake pads 202 and 204. More particularly, each brake pad 202, 204 is placed in firm contact with a lateral face 206 of the brake disk 200 (only one face visible in FIG. 2). In the embodiment of FIG. 2, the brake pads 202, 204 are formed as semi-circular members that include a semi-circular space 208 that enables passage of the shaft 132. Accordingly, the brake pads 202, 204 are each generally C-shaped. Each brake pad 202, 204 is formed of or has a contact surface composed of a relatively high friction material such that the brake pads can be used to resist rotation of the brake disk 200. In some embodiments, the brake pads 202, 204 are constructed of a thermoplastic material.

In the embodiment of FIG. 2, the first brake pad 202 is fixedly mounted to a block 210 that is mounted to or integrated with the bracket base 128. As indicated in FIG. 2, the block 210 is generally rectangular and comprises a groove 212 that accommodates the shaft 132. Because the block 210 is fixed to the bracket 126, which is fixed to the base portion 102, and because the brake pad 202 is fixedly mounted to the block, the brake pad 202 is not configured to move.

The second brake pad 204 is also mounted to a block 214 that is mounted to or integrated with the bracket base 128, and that comprises a groove 215 that accommodates the shaft 132. The second brake pad 204, however, is extensibly mounted to the block 214 with guide shafts 216 (only one guide shaft visible in FIG. 2) that extend from the second brake pad and through openings 218 formed in an end wall 220 of the block. The second brake pad 204 is supported from below by a curved guide surface 222 formed in the block 214. With such an arrangement, the second brake pad 204 can be moved in a linear direction parallel with the longitudinal axis of the shaft 132 with the guide shafts 216 sliding along their respective openings 218. Such movement is controlled, however, by springs 224 that surround the guide shafts 216. The springs 224 are held in compression between an end wall 220 of the block 214 and the second brake pad 204. Because the block 214 is fixed but the second brake pad 204 is not, the second brake pad is displaced away from the end wall 220 by the springs 224 into firm contact with the brake disk 200. The second brake pad 204 pushes against the brake disk 200, thereby forcing the brake disk against the first brake pad 202. Therefore, the brake disk 200 is pinched between the two brake pads 202, 204 under the force of the springs. That pinching provides resistance to rotation of the brake disk 200, and therefore the shaft 132 on which the brake disk is mounted and the display portion 104 to which the shaft, is fixedly secured.

The friction mechanisms described above enable construction of computing devices without friction hinges. Without the need for such friction hinges, space normally reserved for the hinges is available for other uses.

Numerous modifications can be made to the disclosed friction mechanisms. Such modifications include the provision of detents to the disk brake to enable indexing of certain positions of the display portion. For example, a face of the brake disk can comprise a protrusion that is received a depression of one of the brake pads when the display portion is in a closed position. In such a case, a relatively large amount of force will be necessary to initially open the display portion.

In another modification, a face of the brake disk can be sloped like a cam surface. When the springs are progressive springs that require increasing larger force to compress as compression proceeds, relatively little force will be required to pivot the display portion initially but greater force is required to pivot the display portion as the display portion is opened farther.

In a further modification, both brake pads can be urged into contact with the brake disk using springs.

We claim:

1. A friction mechanism for use in a computing device having a base portion and a display portion, the friction mechanism comprising:
a shaft adapted to be supported by the base portion of the computing device and having ends adapted to be fixedly secured to the display portion of the computing device;
a brake disk mounted on the shaft; and
a brake pad in contact with the brake disk that resists rotation of the brake disk such that the brake disk, the shaft on which the brake disk is mounted, and the display portion to which the shaft is fixedly secured cannot freely pivot relative to the base portion of the computing device.

2. The friction mechanism of claim 1, wherein the shaft is constructed of metal.

3. The friction mechanism of claim 1, wherein the brake disk is constructed of metal.

4. The friction mechanism of claim 1, wherein the brake disk is constructed of a plastic material.

5. The friction mechanism of claim 1, wherein the brake pad is constructed of a relatively high-friction material.

6. The friction mechanism of claim 1, wherein the brake pad is semi-circular.

7. The friction mechanism of claim 1, wherein the mechanism comprises two brake pads, one provided on each side of the brake disk.

8. The friction mechanism of claim 1, further comprising a spring that urges the brake pad into contact with the brake disk.

9. The friction mechanism of claim 1, further comprising a mounting bracket with which the friction mechanism mounts to the base portion of the computing device, the mounting bracket including supports that support the shaft and therefore the display portion.

10. A friction mechanism for use in a computing device having a base portion and a display portion, the friction mechanism comprising:
a mounting bracket adapted to mount to the base portion, the mounting bracket including vertical supports;
a shaft supported by the vertical supports of the mounting bracket and having ends adapted to be fixedly secured to the display portion of the computing device such that pivoting of the display portion causes similar pivoting of the shaft;
a brake disk fixedly mounted on the shaft such that pivoting of the shaft causes similar pivoting of the brake disk, the brake disk having first and second lateral faces; and
first and second brake pads comprising high-friction material and respectively contacting the first and second lateral faces of the brake disk; and
a spring that urges the second brake pad into contact with the second lateral face of the brake disk;
wherein friction created between the brake pads and the brake disk resists rotation of the brake disk such that the brake disk, the shaft on which the brake disk is mounted, and the display portion to which the shaft is fixedly secured cannot freely pivot relative to the base portion of the computing device.

11. The friction mechanism of claim 10, further comprising a block to which the first brake pad is fixedly mounted.

12. The friction mechanism of claim 10, further comprising a block to which the second brake pad is extensibly mounted.

13. The friction mechanism of claim 12, wherein the second brake pad comprises guide shafts that extend through openings formed in the block.

14. The friction mechanism of claim 13, wherein the mechanism comprises two springs, one provided on each of the guide shafts.

15. A computing device comprising:
a base portion;
a display portion including hinges with which the display portion is pivotally mounted to the base portion; and
a friction mechanism mounted to the base portion that resists pivoting of the display portion relative to the base portion, the friction mechanism including a mounting bracket mounted to the base portion, a shaft supported by the mounting bracket and having ends that are fixedly secured to the hinges of the display portion, a brake disk mounted on the shaft, and a brake pad in firm contact with the brake disk that resists rotation of the brake disk such that the brake disk, the shaft on which the brake disk is mounted, and the display portion to which the shaft is fixedly secured cannot freely pivot relative to the base portion of the computing device.

16. The computing device of claim 15, wherein the friction mechanism further comprises a spring that urges the brake pad into contact with the brake disk.

17. The computing device of claim 15, wherein the friction mechanism comprises first and second brake pads, one provided on each side of the brake disk.

18. The computing device of claim 17, wherein the friction mechanism further comprises a first block to which the first brake pad is fixedly mounted.

19. The computing device of claim 18, wherein the friction mechanism further comprises a second block to which the second brake pad is extensibly mounted.

20. The computing device of claim 19, wherein the second brake pad comprises guide shafts that extend through openings formed in the second block.
